(19) United States
(12) Patent Application Publication
(10) Pub. No.: US 2026/0282845 A1
(43) Pub. Date: Sep. 17, 2026

(54) SUBSTRATE PROCESSING

(71) Applicant: ASML NETHERLANDS B.V., Veldhoven (NL)

(72) Inventors: Paulus Albertus VAN HAL, Waalre (NL); Adrianus Hendrik KOEVOETS, Mierlo (NL)

(73) Assignee: ASML NETHERLANDS B.V., Veldhoven (NL)

(21) Appl. No.: 19/168,305

(22) PCT Filed: Mar. 21, 2024
(86) PCT No.: PCT/EP2024/057574

§ 371 Date: Sep. 23, 2025

(30) Foreign Application Priority Data
Apr. 21, 2023 (EP) 23169184.1

(51) Int. Cl. H10P 74/20; H10P 70/00; H10P 72/00

(52) U.S. Cl. CPC H10P 74/207; H10P 70/20; H10P 72/0414

(57) ABSTRACT

A method for processing a substrate, the method including: providing a substrate on a support; measuring a property of the substrate and/or of a rinsing liquid; controlling the addition of one or more additives to the rinsing liquid based on the measurement, to adjust the pH value and/or the conductivity of the rinsing liquid to a predetermined value; and providing the rinsing liquid to a surface of the substrate via one or more nozzles. There is also provided a system for processing a substrate, and a method for manufacturing a device.

### CROSS-REFERENCE TO RELATED APPLICATIONS

This application claims priority of EP application 23169184.1 which was filed on 21 Apr. 2023 and which is incorporated herein in its entirety by reference.

### FIELD

The present invention relates to a method for processing a substrate prior to its exposure to radiation in a lithographic apparatus. The present invention also relates to a system for processing a substrate, and to a method for manufacturing a device.

### BACKGROUND TO THE INVENTION

A lithographic apparatus is a machine constructed to apply a desired pattern onto a substrate. A lithographic apparatus can be used, for example, in the manufacture of devices, for example integrated circuits (ICs). A lithographic apparatus may for example project a pattern from a patterning device (e.g., a mask) onto a layer of radiation-sensitive material (resist) provided on a substrate.

The substrate in a lithographic apparatus is typically supported by a support mechanism/substrate holder. When the substrate is a silicon wafer (for example, during integrated circuit manufacture), the support mechanism/substrate holder is typically referred to as a wafer table.

The wavelength of radiation used by a lithographic apparatus to project a pattern onto a substrate determines the minimum size of features that can be formed on that substrate. A lithographic apparatus that uses EUV radiation, that is electromagnetic radiation having a wavelength within the range 4-20 nm, may be used to form smaller features on a substrate than a lithographic apparatus using deep ultraviolet (DUV) radiation (for example with a wavelength of 193 nm).

As the size of features to be formed in a lithographic process reduces, the performance requirements on all aspects of the lithographic apparatus and materials become stricter.

Substrate holders used during device fabrication typically comprise burls, which reduce the influence of contamination by particles on the backside of the substrate.

Typical semiconductor substrates have a thin layer of silicon, for example SiOₓ or SiₓN_{y}, on the backside of the substrate (e.g., the wafer backside), which can lead to the formation of Si-OH groups at the surface. This results in substrate backside surfaces that have high surface energies. Charges (i.e., protons and electrons) are able to migrate over the surface of such substrate backsides.

Before loading a substrate into the lithography apparatus, the backside of the substrate is rinsed to remove contaminant particles. For example, a H₂O rinse with scrubbing on the central part of the substrate may be used. The substrate may then be spin dried. This rinsing step extends substrate holder cleaning intervals, increasing the effective throughput of the lithographic apparatus.

During the spin-coating process insulating substrates (i.e., substrates comprising dielectric material) are charged when rinsing fluids are supplied and additionally when the substrate is dried due to the streaming potential. The amount of charge depends on a range of factors including: the quantity of rinsing fluid used, the length of time that the rinsing fluid is supplied for, the spin speed, the conductivity of the rinsing fluid, and the pH with respect to the iso-electric point of the substrate. Due to the high surface energy of the substrate backside, water may adhere to the surface, leaving adsorbed monolayers of H₂O on the substrate backside even after spin drying. Upon loading the substrate onto the substrate holder, residual water may be present between the substrate backside and the burls of the substrate holder.

Charges may also be present on the substrate due to earlier processing steps. For example, an earlier processing step may lead to charge being trapped between two isolating layers of the substrate. This is demonstrated in FIG. 4. Specifically, FIG. 4 shows: a) fixed charge 42, e.g., caused by a process that was carried out before the final (isolating) layer 41 is deposited, trapping the charges 42; b) charge on outside 43 of substrate, which can be removed, e.g., by making contact with water; c) charges that are both trapped and on the surface of the wafer, where the charges have the same sign 44 and d) charges that are both trapped and on the surface of the wafer, where the charges have opposite signs 45.

Electrochemical corrosion of the burl material at the substrate holder may occur and over time, certain burls may change height. This may lead to increased wafer load grid (WLG), uneven flatness degradation and a local angle focus problem as the image cannot be focused properly on to the substrate. Thus, the substrate holder may no longer meet the strict performance requirements required for lithographic apparatus and must be replaced.

One method of reducing burl reactivity is to apply a cathodic overpotential to the burls to prevent oxidation. However, as taught in Mitraka et al. J. Mater. Chem. A, 2017, 5:4404-4412, applying a cathodic overpotential to the burls in the presence of air may lead to the formation of reactive oxygen species that may corrode the burl.

Another method of reducing burl reactivity is to apply an anodic overpotential to create a passivation layer, which seals the underlying surface and prevents further oxidation. However, passivation layers are only applicable for certain metallic substrates, where the corresponding metal oxide forms a closed oxide layer which is able to prevent further corrosion of the underlying metal layer. For many metals, the metal oxide does not form a closed layer and further corrosion of the underlying metal surface can occur. For carbon-based materials such as DLC or diamond, the corrosion of the carbon-based layers may result in dissolution of the oxide, either in solution or possibly in gaseous species such as CO₂, H₂O and CO.

Hydrophobic wafer backside coatings like hexamethyldisilazane (HMDS), polytetrafluoroethylene (PTFE) and cyclic azasilanes (see for example WO 2021122065 A1) have been used to prevent charge diffusion over the wafer backside. Such coatings are often self-assembled monolayers with hydrophobic end groups. This approach reduces the impact of corrosion because the charge on the wafer backside is no longer mobile: this reduces the oxidation of DLC coatings. However, this approach adds additional process steps and increases complexity and cost. The coatings need to be added before insertion of the wafer into the lithographic system, and removed after lithographic processing. Furthermore, this approach only reduces the mobility of charge: it does not reduce or remove it.

For EUV applications, the impact of charge is via an adhesive force between conducting burls that generate a mirror-charge when a charged substrate backside approaches it. The extra coulombic attraction scales quadratically, and thus the benefit of reducing the charge density and reducing the peak-charge levels by homogenizing also scale quadratically, see FIG. 3.

For EUV, wafer backside coatings do not help to reduce WLG, because they prevent diffusion of charge to conducting burls. This increases the adhesive columbic force between the burls and the charged wafer backside.

A further method that is used to mitigate the impact of charge on the backside of substrates is incorporating carbon dioxide into rinsing water prior to rinsing the wafer backside (see for example US2005133066A1). This results in a solution with a pH of approximately 4.1 and a conductivity of approximately 0.02 mS/cm. Rinsing with this solution may result in a small reduction in charging of the substrate backside, and may distribute the charge profile on a pre-charged substrate backside. However, this is dependent on the specific substrate material. Furthermore, rinsing with a CO₂ solution has a limited impact in resolving WLG drift and flatness degradation. When exposed to air, the supersaturated CO₂ solution will rapidly change in concentration. This results in variability in the CO₂ concentration and pH of the rinsing water during the rinsing process, which adds significantly variability when attempting to remove charge from the substrate. In addition, the conductivity of aqueous CO₂ is not sufficient when rinsing at large spinning speeds, leading to the continued presence of charged regions for spinning speeds above 2000 rpm.

### SUMMARY OF THE INVENTION

In view of the above, there remains a need to develop improved methods and systems for mitigating the effects of charge on substrates.

The present invention relates in particular to a method for processing a substrate, comprising: a) providing a substrate on a support; b) measuring a property of the substrate and/or of a rinsing liquid; c) controlling the addition of one or more additives to the rinsing liquid based on the measurement, to adjust the pH value and/or the conductivity of the rinsing liquid to a predetermined value; and d) providing the rinsing liquid to a first surface of the substrate via a nozzle.

The present invention also relates to a system for processing a substrate, comprising: a) a support for supporting the substrate; b) a nozzle arranged to provide a rinsing liquid to a first surface of the substrate; c) a measurement system configured to measure a property of the substrate and/or the rinsing liquid; and d) a controller configured to adjust the pH value and/or the conductivity of the rinsing liquid based on the measurement of the measurement system, by controlling the addition of one or more additives to the rinsing liquid.

The present invention also relates to a method of manufacturing a device comprising the method for processing a substrate discussed herein.

Such methods and systems permit charge on the substrate, for example on the backside of the substrate, to be controlled prior to insertion of the wafer into a lithographic apparatus. This has significant advantages including minimising the rate of substrate holder corrosion and thus reducing the frequency at which substrate holders must be replaced. This reduces the frequency at which maintenance must be undertaken and substrate holders/wafer tables must be replaced, increasing throughput of the lithographic apparatus and the efficiency of device production.

### BRIEF DESCRIPTION OF THE DRAWINGS

The above and other aspects of the present disclosure will become more apparent from the description of exemplary embodiments, taken in conjunction with the accompanying drawings.

FIG. 1 is a schematic illustration of a lithographic system comprising a lithographic apparatus and a radiation source.

FIG. 2 depicts a schematic overview of a lithographic cell.

FIG. 3 illustrates the impact of charge on wafer load grid (WLG) on a substrate holder.

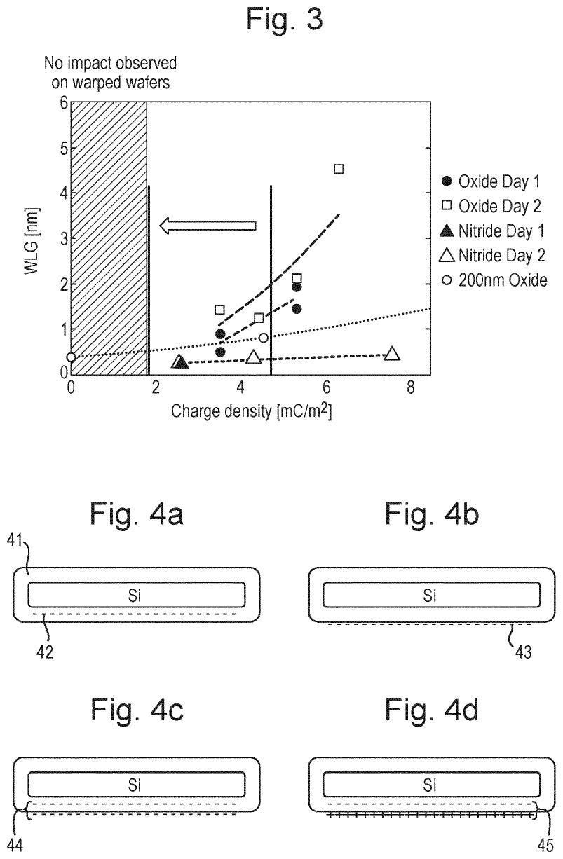

FIGS. 4a, 4b, 4c, and 4d depict different ways in which charges may accumulate on a substrate.

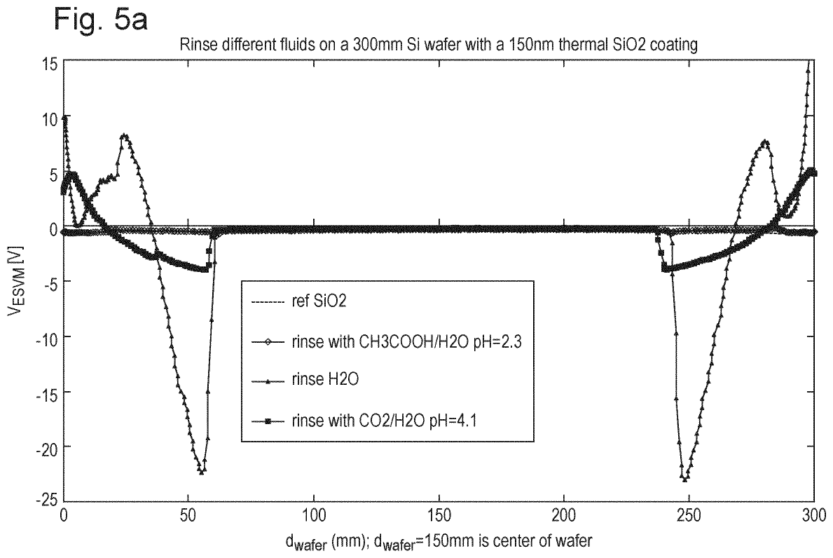

FIG. 5a shows the effect on charge of rinsing a thermal SiO₂ wafer backside with CH₃COOH/H₂O, H₂O, and CO₂/H₂O. FIG. 5b shows a section of the same graph as FIG. 5a with a different y-axis scale.

FIG. 6 shows the effect on charge of rinsing a LPCVD Si₃N₄ wafer backside with CH₃COOH/H₂O, and H₂O.

FIG. 7 shows the effect of rinsing a pre-charged SiO₂ wafer with a water rinse at 2000 rpm, and with an acetic acid rinse at 2400 rpm.

FIG. 8 shows the surface potential at a 150 nm thermal SiO₂ layer coated at a wafer backside with a charge pattern applied in demineralised water spin-rinse before and after treatment with a CH₃COOH solution.

FIG. 9 illustrates a system according to the invention, in which a charge-measurement based spatial profile of the substrate is obtained.

FIG. 10 illustrates a system according to the invention, in which a charge-measurement based spatial profile of the substrate is obtained and FTIR (Fourier transmission infra-red) spectroscopy is performed.

The schematic diagrams and views show the components described below. However, the components depicted in the figures are not to scale.

### DETAILED DESCRIPTION OF THE INVENTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims.

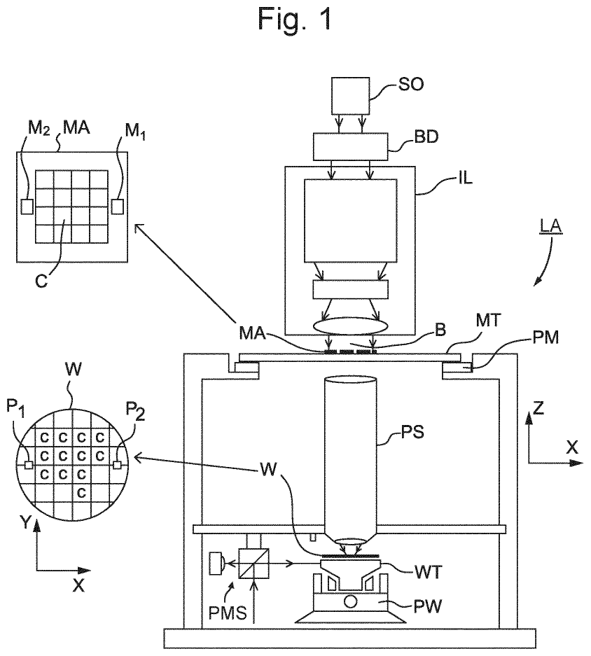

FIG. 1 schematically depicts a lithographic apparatus LA. The lithographic apparatus includes an illumination system (also referred to as illuminator) IL configured to condition a radiation beam B (e.g., EUV radiation or DUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a substrate table) WT constructed to hold a substrate (e.g., a resist coated wafer) W and connected to a second positioner PW configured to accurately position the substrate support WT in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives the radiation beam B from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus may be of a type wherein at least a portion of the substrate W may be covered by an immersion liquid having a relatively high refractive index, e.g., water, so as to fill an immersion space between the projection system PS and the substrate W-which is also referred to as immersion lithography. More information on immersion techniques is given in US 6,952,253, which is incorporated herein by reference.

The lithographic apparatus may be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus may comprise a measurement stage (not depicted in FIG. 1). The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system PMS, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

In a lithographic apparatus it is necessary to position with great accuracy the upper surface of a substrate or wafer to be exposed in the plane of best focus of the aerial image of the pattern projected by the projection system. To achieve this, the substrate or wafer can be held on a substrate holder or wafer table. The surface of the substrate holder that supports the substrate can be provided with a plurality of burls whose distal ends can be coplanar in a nominal support plane. The burls, though numerous, may be small in cross-sectional area parallel to the support plane so that the total cross-sectional area of their distal ends is a few percent, e.g. less than 5%, of the surface area of the substrate. The gas pressure in the space between the substrate holder and the substrate may be reduced relative to the pressure above the substrate to create a force clamping the substrate to the substrate holder.

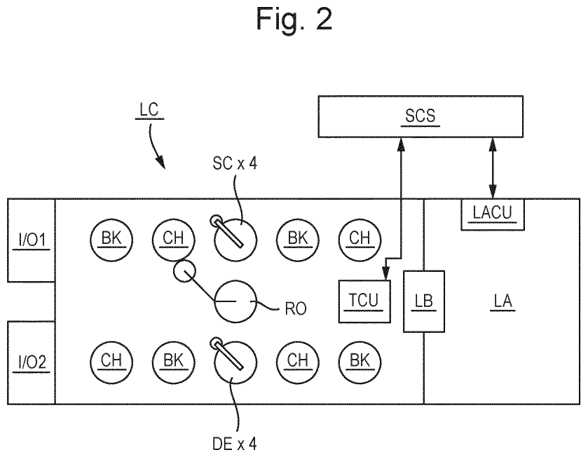

As shown in FIG. 2 the lithographic apparatus LA may form part of a lithographic cell LC, also sometimes referred to as a lithocell or (litho)cluster, which often also includes apparatus to perform pre-and post-exposure processes on a substrate W. Conventionally these include spin coaters SC to deposit resist layers, developers DE to develop exposed resist, chill plates CH and bake plates BK, e.g. for conditioning the temperature of substrates W e.g. for conditioning solvents in the resist layers. A substrate handler, or robot, RO picks up substrates W from input/output ports I/O1, I/O2, moves them between the different process apparatus and delivers the substrates W to the loading bay LB of the lithographic apparatus LA. The devices in the lithocell, which are often also collectively referred to as the track, are typically under the control of a track control unit TCU that in itself may be controlled by a supervisory control system SCS, which may also control the lithographic apparatus LA, e.g. via lithography control unit LACU.

A wafer as discussed herein is one example of a substrate that may be supported by a substrate holder. When the substrate is referred to as a wafer, the substrate holder is typically referred to as a wafer table.

Contact between the substrate backside and the burl material in the presence of water can lead to electrochemical corrosion of the burl material, for example the diamond-like carbon (DLC) coating at the burls. Over time, certain burls may change height, resulting in an uneven flatness degradation and a local angle focus problem as the image cannot be focussed properly on to the substrate. Thus, the substrate holder may no longer meet the strict performance requirements required for lithographic apparatus and must be replaced. Minimising the rate of burl corrosion is therefore key to maximising substrate holder life and efficiency of device production.

In addition to the above, during loading the substrate makes contact with certain points of the substrate holder, which can introduce displacement errors in the x and y directions. These errors may be exacerbated when the substrate backside is charged. These errors have been observed to drift over time and are reflected in the wafer load grid (WLG) drift.

Excluding the wet substrate rinsing step results in no measurable flatness degradation after 1000 substrate passes in an accelerated test environment. However, the wet substrate rinsing step cannot be removed entirely as this would increase the frequency of substrate holder cleaning, reducing throughput of the lithographic apparatus. Thus, reducing the quantity of water and/or surface charges present on the substrate backside following washing is key to minimising flatness degradation.

Wafer load grid (WLG) is also a serious issue for lithography. Local damage of substrate holders in the x, y and/or z direction has a negative impact on the overlay (i.e., the error in position of features in one layer of the patterned substrate relative to features in another layer, which may arise from errors in positioning of the substrate with respect to the aerial image at the time of exposure) at the nanometer level. Over time, WLG may drift to higher values, resulting in overlay issues and reducing the lifetime of the substrate holder. Minimising the rate of burl corrosion is also key to minimising the rate of drift of WLG.

WLG of electrostatic clamps (ESCs) used in extreme ultra-violet (EUV) lithography is also problematic, and limits the effective life-time of the ESC for high-volume device production using EUV lithography. Minimising the rate of burl corrosion is also important in minimising ESC WLG.

The present invention arises from the surprising finding that it is possible to control the charge on a substrate by modifying the rinsing liquid provided to the substrate as part of the cleaning step prior to insertion of the substrate into a lithography apparatus. For example, it is possible to either decrease the charge on the wafer, or to maintain the charge depending on a number of factors including: (i) presence of existing charge on the substrate before the rinsing step; (ii) isoelectric point (IEP) of the substrate when in contact with water; (iii) pH value of the rinsing liquid; and (iv) conductivity of the rinsing liquid. Controlling the charge on the substrate before it is inserted into a lithography apparatus provides a number of advantages. For example, reducing the charge on the substrate may decrease the rate of substrate holder flatness degradation and/or wafer load grid (WLG), reduce the rate of electrochemical corrosion of burls within the lithography apparatus etc.

The invention in particular provides a method for processing a substrate, comprising: a) providing a substrate on a support; b) measuring a property of the substrate and/or of a rinsing liquid; c) controlling the addition of one or more additives to the rinsing liquid based on the measurement, to adjust the pH value and/or the conductivity of the rinsing liquid to a predetermined value; and d) providing the rinsing liquid to a first surface of the substrate via a nozzle (or alike).

The measured property may be at least one of: (i) charge on the substrate; (ii) isoelectric point (IEP) of the first surface of the substrate when in contact with water; (iii) pH value of the rinsing liquid; and (iv) conductivity of the rinsing liquid. The measured property may be at least two of: (i) charge on the substrate; (ii) isoelectric point (IEP) of the first surface of the substrate when in contact with water; (iii) pH value of the rinsing liquid; and (iv) conductivity of the rinsing liquid. The measured property may be at least three of: (i) charge on the substrate; (ii) isoelectric point (IEP) of the first surface of the substrate when in contact with water; (iii) pH value of the rinsing liquid; and (iv) conductivity of the rinsing liquid. The measured property may be all of: (i) charge on the substrate; (ii) isoelectric point (IEP) of the first surface of the substrate when in contact with water; (iii) pH value of the rinsing liquid; and (iv) conductivity of the rinsing liquid. For example, the measured property may be charge on the substrate. Alternatively, the measured property may be the isoelectric point (IEP) of the first surface of the substrate when in contact with water. Alternatively, the measured property may be the pH value of the rinsing liquid. Alternatively, the measured property may be the conductivity of the rinsing liquid. The measured property may be both the charge on the substrate; and the isoelectric point (IEP) of the first surface of the substrate when in contact with water. The measured property may be both the charge on the substrate; and the pH value of the rinsing liquid. The measured property may be both the isoelectric point (IEP) of the first surface of the substrate when in contact with water; and pH value of the rinsing liquid. The measured property may be both the charge on the substrate; and the conductivity of the rinsing liquid. The measured property may be both the pH value of the rinsing liquid; and the conductivity of the rinsing liquid. The measured property may be both the isoelectric point (IEP) of the first surface of the substrate when in contact with water; and the conductivity of the rinsing liquid.

The rinsing liquid is provided to a first surface of the substrate via a nozzle. Thus, the first surface of the substrate may be cleaned by the rinsing liquid in the method of the invention. The rinsing liquid may be provided to a backside surface or to a frontside surface of the substrate. Preferably, the rinsing liquid is provided to a backside surface of the substrate. Thus, a backside surface of the substrate may be cleaned by the rinsing liquid in the method of the invention. “Backside surface of the substrate” in the context of the present invention refers to the surface of the substrate that is opposite to the surface of the substrate comprising photoresist. In other words, the backside surface of the substrate is the side of the substrate that is opposite to the side of the substrate that is exposed to radiation in the lithography apparatus after the cleaning is performed. “Frontside surface of the substrate” in the context of the present invention refers to the surface of the substrate that is exposed to radiation in the lithography apparatus.

The measured property may be measured at a backside surface of the substrate. Thus, charge may be measured at one or more points (or locations) of the backside surface of the substrate. When the IEP of the first surface of the substrate is measured when in contact with water, the first surface may be a backside surface of the substrate.

When the measured property is a charge on the substrate, a charge-measurement based spatial profile of the substrate may be measured. Hence, a mapping of the (local) charge at the substrate may be obtained-a charge map. Alternatively, one or more point charges may be measured at one or more points of the surface of the substrate.

The measured property may be measured by any suitable apparatus. For example, a FTIR (Fourier transmission infrared) spectrometer may be used to determine the composition of the substrate, and in turn used to estimate or to calculate the IEP of the first surface of the substrate when in contact with water. For example, measuring the IEP of the first surface may comprise using FTIR to identify the composition of the first surface and determining the IEP using known values for that composition. A pH sensor or probe may be used to calculate the pH of the rinsing liquid. Charge may be measured by any suitable apparatus, for example an electrostatic voltmeter may be used. Conductivity may be measured by any suitable apparatus, for example an electrical conductivity meter may be used.

The isoelectric point (IEP) of the first surface of the substrate (for example, the backside surface of the substrate) may be determined based on information about previous steps in the manufacturing process. The IEP may alternatively or additionally be determined based an in-situ or in-track FTIR measurement. The optical transmission of a given wafer is dependent on the material properties. For example, the optical transmission of SiO2 different to that of Si, resulting in a different FTIR measurement. This information may be used together with information about any earlier manufacturing steps to determine or estimate the IEP of the wafer surface, for example by using known IEP values for the composition of the wafer surface. This information may be used to determine properties of the one or more additives to be added to the rinsing liquid, in order to modulate the pH value of the rinsing liquid to the predetermined value. For example, the specific compound or compounds used in the one or more additives, their concentrations, pH, the volume of additive to be added to the rinsing liquid etc. may all be determined.

When the measured property is a property of the substrate, the property may be measured at any point of the wafer track. Alternatively, the measured property of the substrate may be measured when the substrate is in transit between pieces of apparatus. For example, the measured property of the substrate may be measured while the substrate is inside a front opening unified pod (FOUP).

The present invention allows the charge on the substrate to be controlled by modifying the rinsing liquid provided to the substrate. In particular, the addition of one or more additives to the rinsing liquid based on the measurement of the measurement system may be used to control the properties of the rinsing liquid. For example, addition of the one or more additives may decrease the pH of the rinsing liquid and/or increase the conductivity of the rinsing liquid.

The present invention also allows the charge on the substrate to be controlled locally, i.e., at specific regions of the substrate, if desired. For example, the method of the invention may be performed multiple times on a single wafer, each time focused on a different specific location on the wafer surface. Thus, local charge at a particular local region of the wafer may be controlled using the method of the invention.

A given substrate material has a set isoelectric point (IEP) when in contact with water. When the pH of the water matches the IEP, the zeta potential is 0, and there is no net flow of charge when the water is in contact with the surface of the substrate. Thus, the rinsing liquid at this pH can flow over the substrate with no net transfer of charge. When the pH of the water is greater than the IEP of the substrate surface, the zeta potential is negative, and the substrate will charge negatively when water flows over it. Thus, a high pH rinsing liquid can be used to either add negative charge to a substrate, or to remove positive charge from the substrate. Conversely, when the pH of the water is less than the IEP of the substrate surface, the zeta potential is positive, and the substrate will charge positively when water flows over it. Thus, a low pH rinsing liquid can be used to either add positive charge to a substrate, or to remove negative charge from the substrate.

Thus, the composition of the outer surface of the insulating dielectric layer (e.g., SiOx, SiN) determines the interaction with the rinsing fluid. The pH of the rinsing liquid can be adjusted based on the surface composition in order to regulate the charge.

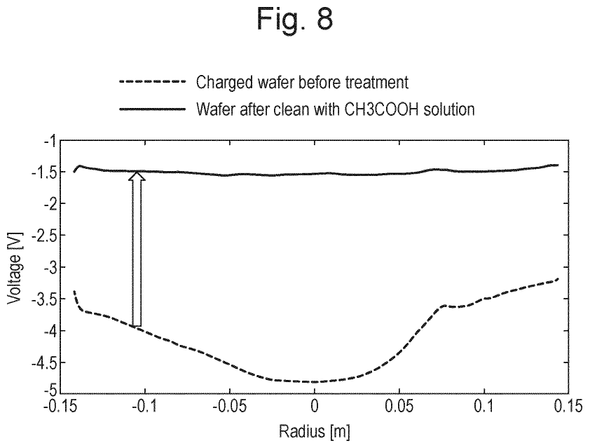

FIG. 8.6 at page 98 of The Zeta Potential for Solid Surface Analysis, by Thomas Luxbacher (2014) demonstrates the effect on IEP when SiN is untreated and then properly cleaned, yielding SiN with a larger IEP. Specifically, that figure shows a zeta potential measurement using 1 mM KCI to measure the isoelectric point (IEP) for different typical substrate backside materials (SiO₂ and SiN) in contact with water with different acidities (pH). The isoelectric point (IEP) is defined as the pH at which there is equilibrium between the positive and negative charges on the surface. If the pH of the rinsing liquid is above (i.e., to the right) of the IEP, the substrate will charge negatively. If the pH of the rinsing liquid is below (i.e., to the left) of the IEP, the substrate will charge positively.

The conductivity of the rinsing liquid also has a significant impact. The greater the conductivity of the rinsing liquid, the more easily charge can be transferred to or from the substrate during rinsing with the rinsing liquid. Typically, the rinsing liquid used to rinse the substrate has a conductivity of 0.1 mS/cm or greater, or about 0.2 mS/cm or greater, or about 0.3 mS/cm or greater, or about 0.4 mS/cm or greater, preferably about 0.5 mS/cm or greater.

It will thus be appreciated that addition of one or more additives to the rinsing liquid may be adjusted in order to impart, remove or maintain charge on the substrate when the substrate is cleaned using the rinsing liquid.

The charge on the substrate may be decreased by providing the rinsing liquid to the surface of the substrate. For example, if the charge on the substrate before rinsing is negative, the pH of the rinsing liquid may be adjusted to lower the pH to below the isoelectric point of the substrate. Upon rinsing, the net charge on the substrate may decrease. Alternatively, if the charge on the substrate before rinsing is positive, the pH of the rinsing liquid may be adjusted to increase the pH to above the isoelectric point of the substrate. Upon rinsing, the net charge on the substrate may decrease.

The charge on the substrate may be increased by providing the rinsing liquid to the surface of the substrate. For example, if the charge on the substrate before rinsing is negative, the pH of the rinsing liquid may be adjusted to increase the pH to above the isoelectric point of the substrate. Upon rinsing, the net charge on the substrate will increase. Alternatively, if the charge on the substrate before rinsing is positive, the pH of the rinsing liquid may be adjusted to decrease the pH to below the isoelectric point of the substrate. Upon rinsing, the net charge on the substrate will increase.

The charge on the substrate may be substantially unchanged by providing the rinsing liquid to the surface of the substrate. In this case, the pH of the rinsing liquid may be adjusted to substantially match the isoelectric point of the substrate. Upon rinsing, the net charge on the substrate will not change. Thus, an originally uncharged substrate may remain uncharged following rinsing. Alternatively, if it is intended to retain a given charge on the substrate, the pH of the rinsing liquid may be adjusted to match the IEP of the substrate surface, and no net transfer of charge will occur when the substrate is rinsed with the rinsing liquid.

The rinsing liquid is typically an aqueous solution.

The one or more additives may be in any suitable form. The one or more additives are typically aqueous solutions. Alternatively, one or more of the additives may be a solid that dissolves when added to the rinsing liquid. Typically, the one or more additives comprise one or more organic acids. “Organic acid” in the context of the present invention means an organic compound with weak acidic properties that does not dissociate completely in aqueous solution. The one or more organic acids typically comprise from 1 to 10 carbon atoms, preferably 1 to 3 carbon atoms. The one or more organic acids may comprise at least one compound comprising at least one group selected from a carboxyl group, a sulfo group, a thiol group, an alcohol group, an enol group, and a phenol group. The one or more organic acids preferably comprise at least one compound comprising a carboxyl group. The one or more organic acids may comprise at least one compound selected from: an amino acid, an acid with unsaturated groups (for example, an acid comprising double or triple bonds), or a fluorinated organic acid.

When the additive comprises one or more organic acids, the organic acid is not particularly limited. For example, the one or more organic acids may comprise at least one of formic acid, acetic acid, Glycolic acid, Glyoxylic acid, Oxalic acid, Propionic acid, Acrylic acid, Propiolic acid, Lactic acid, 3-Hydroxypropionic acid, Glyceric acid, Pyruvic acid, 3-oxopropanoic acid, 2,3-dioxopropanoic acid, Malonic acid, Tartronic acid, 2,2-dihydroxypropanedioic acid, Mesoxalic acid, Glycidic acid, butyric acid, isobutyric acid, crotonic acid, isocrotonic acid, methacrylic acid, vinylacetic acid, tetrolic acid, acetoacetic acid, succinic acid, fumaric acid, maleic acid, malic acid, tartaric acid, oxaloacetic acid, valeric acid, caproic acid, citric acid, aconitic acid, isocitric acid, sorbic acid, enanthic acid, pimelic acid, benzoic acid, salicylic acid, caprylic acid, phthalic acid, sophthalic acid, terephthalic acid, pelargonic acid, trimesic acid, cinnamic acid, capric acid, sebacic acid, glutaric acid, adipic acid, pimelic acid, trifluoroacetic acid and uric acid.

It is preferable for the one or more organic acids to have a boiling point of from about 80 to about 150° C. at a pressure of 1 atm. The organic acid having a boiling point that is similar to the boiling point of water is advantageous because the rate of evaporation of the acid is similar to that of water. Thus, removing excess rinsing liquid (including water and any organic acid) following rinsing the substrate is straightforward, and little or no residue of the one or more additives remains on the substrate following the rinsing step. For example, spin drying may be used to remove excess water and organic acid. In addition, the concentration of the organic acid in water remains relatively stable because the water and organic acid evaporate at approximately the same rate. The one or more organic acids may have a boiling point of from about 85 to about 145° C., or from about 90 to about 140° C., or from about 95 to about 135° C., or from about 100 to about 130° C. at a pressure of 1 atm.

To minimize the impact of residues, additives containing only C, O, and H atoms are preferred.

When the additive comprises one or more organic acids, the one or more organic acids may comprise at least one of formic acid, acetic acid, or propionic acid. Preferably, the one or more organic acids comprise acetic acid (CH₃COOH).

The additive may comprise two or more organic acids. Thus, the properties of the rinsing liquid may be modified to a particular pH and/or conductivity by utilising multiple organic acids as the additive. For example, the additive may comprise acetic acid and citric acid.

The one or more additives may also comprise one or more additional compounds that may impart useful properties on the rinsing liquid and/or improve the processing of the substrate. For example, the one or more additional compounds may comprise one or more of: soaps, inhibitors, anti-oxidants, and radical scavengers.

Controlling the addition of the one or more additives adjusts the pH value and/or the conductivity of the rinsing liquid to a predetermined value. The value is predetermined based on factors including: 1) the specific substrate that is used and the isoelectric point of its surface; 2) whether it is intended to remove, add or maintain the existing charge on the substrate; 3) the sign and location of any existing charge on the substrate.

As discussed above, when the pH of the water is greater than the IEP of the substrate surface, the substrate will charge negatively when water flows over it. Conversely, when the pH of the water is less than the IEP of the substrate surface, the substrate will charge positively when water flows over it. For example, the predetermined pH value may be from about 1 to about 4.5, or from about 2 to about 3.5, or from about 2.5 to about 3. Alternatively, the predetermined pH value may be from about 1.5 to about 2.5, or from about 2.5 to about 3.5, or from about 3.5 to about 4.5. Alternatively, the predetermined pH value may be from about, 1 to about 3, or from about 1 to about 2, or from about 1 to about 1.75.

Controlling the addition of the one or more additives may adjust the conductivity of the rinsing liquid to a predetermined value. The conductivity of the rinsing liquid following addition of the one or more additives may be about 0.1 mS/cm or greater, or about 0.2 mS/cm or greater, or about 0.3 mS/cm or greater, or about 0.4 mS/cm or greater, and is preferably about 0.5 mS/cm or greater. A conductivity of about 0.5 mS/cm or greater is preferable to facilitate rapid transfer of charges between the substrate and the rinsing liquid. For example, the conductivity of the rinsing liquid following addition of the one or more additives may be from about 0.1 mS/cm to about 5 mS/cm, or from about 0.2 mS/cm to about 4 mS/cm, or from about 0.3 mS/cm to about 3 mS/cm, or from about 0.4 mS/cm to about 2.5 mS/cm, or from about 0.45 mS/cm to about 2 mS/cm.

The IEP depends on the pK₁ and pK₂ of the outer surface composition. For example, for hydroxylated SiO₂, pK₁=6, and pK₂=−2 for SiOH. The IEP=(pK₁+pK₂)/2 and results in a value of IEP for SiO₂ of 2-3. For Si₃N₄, the pK₁ and pK₂ are 8 and 5-6, resulting in an IEP of 6-7.

Hence, rinsing with H2O or CO₂/H₂O having a pH of between 4 and 6 results in a positively charged Si₃N₄ and a negatively charged SiO₂. The conductivity of H₂O is 0.004 mS/cm, while the conductivity of the CO₂/H₂O system is 0.02 mS/cm. Hence, the CO₂/H₂O cannot prevent charging SiO₂-based wafers, as the pH of the CO₂/H₂O rinsing liquid is not low enough.

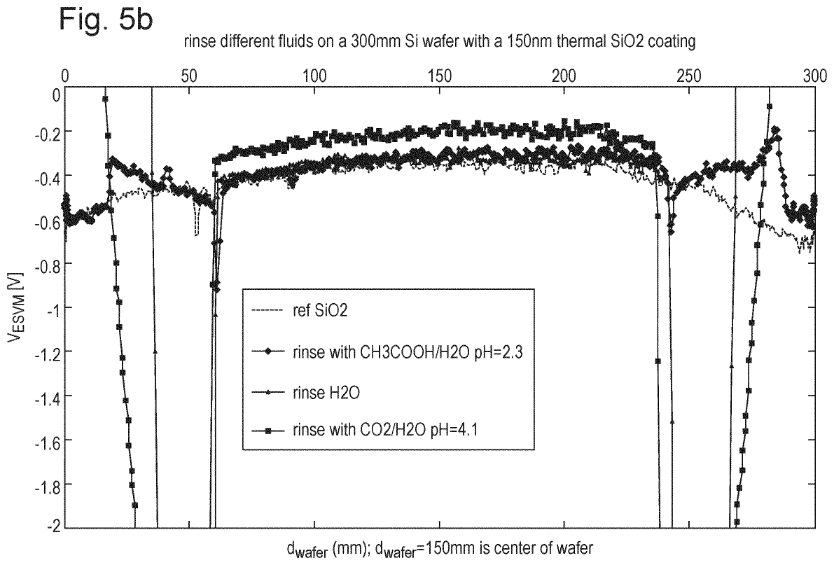

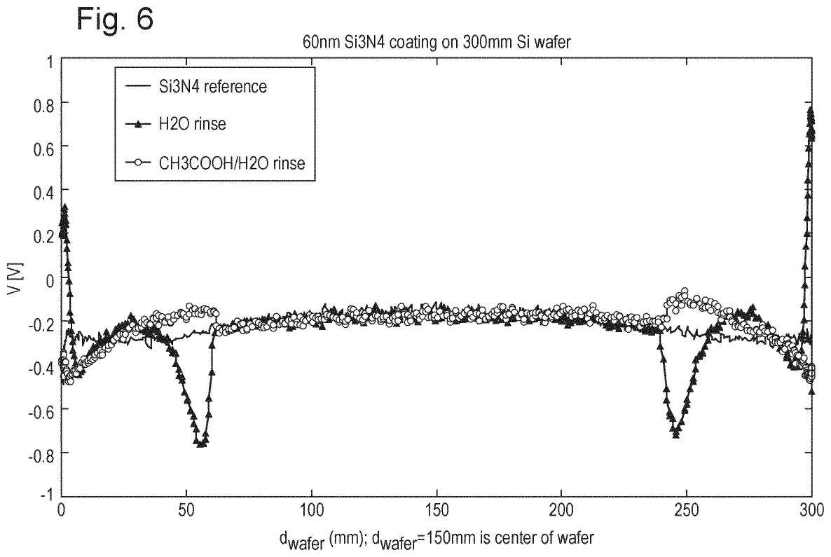

In contrast, by adding a slightly stronger acid, acetic acid (CH₃COOH), a rinsing liquid with a pH of >3 and a conductivity of >0.7 mS/cm can be attained. Rinsing a SiO₂ surface with a rinsing liquid at pH 2.9 causes no net change in the charge on the surface of the substrate (see FIG. 5). On a Si₃N₄ surface, the total charge is reduced (see FIG. 6).

Conversely, tuning the pH of the acetic acid/water rinsing liquid to pH 4.9 (conductivity 0.0046 mS/cm) and rinsing a SiO₂ substrate results in the substrate charging negatively.

Specifically, FIG. 5a shows the effect on charge of rinsing a substrate backside with CH₃COOH/H₂O, H₂O, and CO₂/H₂O during 18 sec supply of the rinsing fluid at a spin speed of 2400 rpm, and drying for 20 sec at 2400 rpm. The rinsing fluid is supplied at a distance of d=80 mm from the center onto a rotating 150 nm thick thermal SiO₂ layer at the wafer. GRIP method is used, in which mechanical contact points are used in the wafer-core to ground the core electrically during the recording of the potential using an electrostatic voltmeter (ESVM). Data for a non-rinsed substrate is included for reference. FIG. 5b shows a section of the same graph as FIG. 5a with a different y-axis scale, demonstrating that rinsing with a solution of acetic acid results in an uncharged substrate.

FIG. 6 shows the effect on charge of rinsing a substrate backside with CH₃COOH/H₂O versus H₂O only during 18 sec supply of the rinsing fluid at a spin speed of 2400 rpm, and drying for 20 sec at 2400 rpm. The rinsing fluid is supplied at a distance of d=80 mm from the center onto a rotating 60 nm LPCVD Si₃N₄ coated wafer backside.

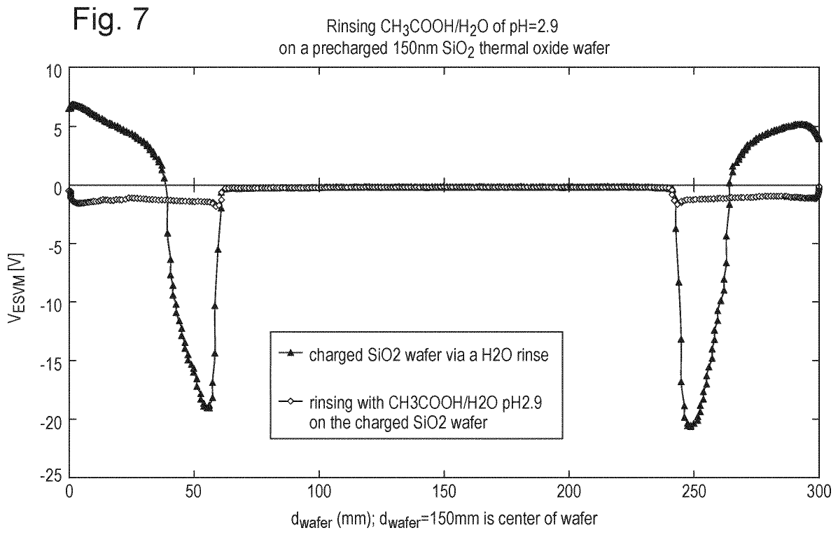

FIG. 7 shows the effect of rinsing a pre-charged SiO₂ wafer with a water rinse at 2000 rpm, and with an acetic acid rinse at 2400 rpm. The acetic acid rinse results in a significant reduction of the charges. A 150 nm thick SiO₂ layer at the wafer backside was charged using water. The wafer backside was rinsed with CH₃COOH/H₂O solution at pH=2.9 at 2400 rpm for 18 s, and dried for 20 s at 2400 rpm, resulting in a reduced charge at the SiO₂ wafer backside.

FIG. 8 shows the reduction in charge when a charged wafer is cleaned with a CH₃COOH/H₂O solution.

The specific method used to control the addition of one more additives to the rinsing liquid based on the measurement(s) made is not particularly limited, provided that it results in the pH value and/or the conductivity of the rinsing liquid reaching the predetermined value. For example, addition of one or more additives the rinsing liquid may commence, to adjust the pH and/or the conductivity of the rinsing liquid to the predetermined value. Addition of the one or more additives to the rinsing liquid may stop, to adjust the pH and/or the conductivity of the rinsing liquid to the predetermined value. The number of additives being added may be modulated to either increase the number of additives being added or to decrease the number of additives being added. The concentration, pH, volume, and/or pressure of the one or more additives may be increased or decreased so at to modify the pH and/or the conductivity of the rinsing liquid. The compound or compounds of the one or more additives may be changed in order to modify the pH and/or the conductivity of the rinsing liquid (for example, by replacing a very weak organic acid additive such as a phenol with a carboxylic acid additive). The time that the one or more additives is added for may be increased and/or decreased. If the pH and/or the conductivity of the rinsing liquid is already at the predetermined value, controlling the addition of the one or more additives may mean that no change is made to the addition of the one or more additives, to maintain the pH and/or conductivity of the rinsing liquid at the predetermined value.

The method of the invention may further comprise measuring one or more properties of the rinsing liquid following addition of the one or more additives to the rinsing liquid. For example, the pH of the rinsing liquid may be measured following addition of the one or more additives in step c). Alternatively or additionally, the conductivity of the rinsing liquid may be measured following addition of the one or more additives in step c). Following this measurement, the method may comprise further controlling the addition of one or more additives to the rinsing liquid based on the measurement, to adjust the pH value and/or the conductivity of the rinsing liquid to the predetermined value. For example, one or more further additives may be added to the rinsing liquid.

The one or more additives may be introduced to the rinsing liquid by any method known in the art. For example, the one or the one or more additives may be introduced to the rinsing liquid by actuating one or more control valves.

The method of the invention may further comprise spinning the substrate while the rinsing liquid is provided to the first surface of the substrate. For example, the substrate may be spun at from about 1000 rpm to about 3000 rpm, or from about 1200 rpm to about 2800 rpm, or from about 1400 rpm to about 2600 rpm, or from about 1600 rpm to about 2400 rpm.

The method of the invention may further comprise adapting the liquid pressure of the rinsing liquid or the rotational velocity at which the substrate is spun during the rinsing based on the value of the measured property in step b), for example based on the charge on the substrate. The liquid pressure of the rinsing liquid may be either increased or decreased based on the measured property. The rotational velocity of the substrate may be either increased or decreased based on the measured property.

The method of the invention may further comprise adapting a radial position of the rinsing liquid when provided to the first surface of the substrate with respect to a rotational axis, being the axis of rotation during spinning of the substrate, while the substrate is rotated (spun) around the rotational axis. In addition, the composition of the rinsing liquid may be adapted as a function of the radial position. Thus, the one or more additives may be introduced to the rinsing liquid as a function of the radial position of the rinsing liquid when provided to the substrate.

The substrate can be made of any semiconducting material known in the art that may be used to produce substrates. For example, the substrate may be a silicon wafer, a silicon nitride wafer, a silicon oxide wafer, a silicon carbide wafer, a gallium nitride wafer, a gallium arsenide wafer or an aluminium titanium carbide wafer. Preferably, the substrate is a silicon wafer, a silicon nitride wafer, or a silicon oxide wafer. The substrate may comprise one or more substrate coatings, provided that the rinsing liquid does not react with or dissolve the one or more coatings. The one or more coatings may comprise a carbon-based polymer coating.

The invention also provides a system that may be used to carry out the method discussed herein. In particular, the invention provides a system for processing a substrate, comprising: a) a support for supporting the substrate; b) a nozzle arranged to provide a rinsing liquid to a first surface of the substrate; c) a measurement system configured to measure a property of the substrate and/or the rinsing liquid; and d) a controller configured to adjust the pH value and/or the conductivity of the rinsing liquid based on the measurement of the measurement system, by controlling the addition of one or more additives to the rinsing liquid.

According to the invention, the system may comprise one or more nozzles arranged to provide a rinsing liquid to a substrate surface. Each of the one or more nozzles may provide different rinsing liquids. For example, a first nozzle may provide a first rinsing liquid and a second nozzle may provide a second rinsing liquid. The first and second rinsing liquids may have different properties. The first and second rinsing liquids may have the same properties. The one or more nozzles may be arranged in a 1D or a 2D array.

The position of each of the one or more nozzles may be controlled by the controller arranged in the system. That is, the position of each of the one or more nozzles with respect to the substrate, for example with respect to the center of the substrate, may be controlled by the controller. As such, the position of each of the one or more nozzles may be defined as a radial position, being a position in respect to an axis of rotation of the substrate during spinning of the substrate. By changing the radial position of a nozzle while providing a rinsing liquid to the substrate (while spinning the substrate) the whole area of interest can be provided (and covered) with the rinsing liquid.

The position of each of the one or more nozzles may be set or defined by the spatial properties at the substrate. This may be a mapping of the (local) charge at the substrate, forming a charge map of the substrate.

The system may be configured to measure at least one of: (i) charge on the substrate; (ii) isoelectric point (IEP) of the first surface of the substrate when in contact with water; (iii) pH value of the rinsing liquid; and (iv) conductivity of the rinsing liquid. The system may be configured to measure at least two of: (i) charge on the substrate; (ii) isoelectric point (IEP) of the first surface of the substrate when in contact with water; (iii) pH value of the rinsing liquid; and (iv) conductivity of the rinsing liquid. The system may be configured to measure at least three of: (i) charge on the substrate; (ii) isoelectric point (IEP) of the first surface of the substrate when in contact with water; (iii) pH value of the rinsing liquid; and (iv) conductivity of the rinsing liquid. The system may be configured to measure all of: (i) charge on the substrate; (ii) isoelectric point (IEP) of the first surface of the substrate when in contact with water; (iii) pH value of the rinsing liquid; and (iv) conductivity of the rinsing liquid. For example, the system may be configured to measure charge on the substrate. Alternatively, the system may be configured to measure the isoelectric point (IEP) of the first surface of the substrate when in contact with water. Alternatively, the system may be configured to measure the pH value of the rinsing liquid. Alternatively, the system may be configured to measure the conductivity of the rinsing liquid. The system may be configured to measure both the charge on the substrate; and the isoelectric point (IEP) of the first surface of the substrate when in contact with water. The system may be configured to measure both the charge on the substrate; and the pH value of the rinsing liquid. The system may be configured to measure both the isoelectric point (IEP) of the first surface of the substrate when in contact with water; and pH value of the rinsing liquid. The system may be configured to measure both the charge on the substrate; and the conductivity of the rinsing liquid. The system may be configured to measure both the pH value of the rinsing liquid; and the conductivity of the rinsing liquid. The system may be configured to measure both the isoelectric point (IEP) of the first surface of the substrate when in contact with water; and the conductivity of the rinsing liquid.

The nozzle is arranged to provide the rinsing liquid to a first surface of the substrate. Thus, the system of the invention may be used to clean the first surface of the substrate using the rinsing liquid. The nozzle may be arranged to provide the rinsing liquid to a backside surface or to a frontside surface of the substrate. Preferably, nozzle is arranged to provide the rinsing liquid to a backside surface of the substrate. Thus, the system of the invention is preferably used to clean the backside surface of the substrate using the rinsing liquid.

The system may be configured to measure a property at a backside surface of the substrate. Thus, a charge may be measured at one or more points (or locations) of the backside surface of the substrate. When the IEP of the first surface of the substrate is measured when in contact with water, the first surface may be backside surface of the substrate.

The system may be configured to measure a charge-measurement based spatial profile of the substrate may be measured. Hence, a mapping of the (local) charge at the substrate may be obtained-a charge map. Alternatively, the system may be configured to measure one or more point charges at one or more points of the surface of the substrate. The measurement system may comprise any suitable apparatus suitable for measuring a charge, for example, an electrostatic voltmeter.

The measurement system may comprise any suitable apparatus for measuring a property of the substrate. For example, the measurement system may comprise a FTIR (Fourier transmission infrared) spectrometer, which may be used to determine the composition of the substrate, and may in turn used to estimate or to calculate the IEP a first surface of the substrate when in contact with water. The measurement system may comprise a pH sensor or probe to calculate the pH of the rinsing liquid. The measurement system may comprise an apparatus suitable for measuring charge, for example, an electrostatic voltmeter. The measurement system may comprise a sensor for measuring conductivity, for example an electrical conductivity meter.

The rinsing liquid and one or more additives may be as defined above in relation to the method of the invention.

The system of the invention permits the addition of the one or more additives to be controlled, in order to adjust the pH value and/or the conductivity of the rinsing liquid to a predetermined value. The value is predetermined based on factors including: 1) the specific substrate that is used and the isoelectric point of its surface; 2) whether it is intended to remove, add or maintain the existing charge on the substrate; 3) the sign and location of any existing charge on the substrate. For example, the predetermined pH value may be from about 1 to about 4.5, or from about 2 to about 3.5, or from about 2.5 to about 3. Alternatively, the predetermined pH value may be from about 1.5 to about 2.5, or from about 2.5 to about 3.5, or from about 3.5 to about 4.5. For example, the predetermined conductivity value may be about 0.1 mS/cm or greater, or about 0.2 mS/cm or greater, or about 0.3 mS/cm or greater, or about 0.4 mS/cm or greater, and is preferably about 0.5 mS/cm or greater. For example, predetermined conductivity value may be from about 0.1 mS/cm to about 5 mS/cm, or from about 0.2 mS/cm to about 4 mS/cm, or from about 0.3 mS/cm to about 3 mS/cm, or from about 0.4 mS/cm to about 2.5 mS/cm, or from about 0.45 mS/cm to about 2 mS/cm.

Controlling the addition of the one or more additives may adjust the conductivity of the rinsing liquid to the predetermined value.

The system of the invention may further comprise a second measurement system configured to measure one or more properties of the rinsing liquid following addition of the one or more additives to the rinsing liquid. For example, second measurement system may be configured to measure the pH of the rinsing liquid following addition of the one or more additives to the rinsing liquid. The second measurement system may alternatively or additionally be configured to measure the conductivity of the rinsing liquid may be measured following addition of the one or more additives.

The system may comprise one or more actuators and one or more control valves. One or more of the control valves may be configured to control the addition of one or more aqueous additives to the rinsing liquid.

The system of the invention may be configured to spin the substrate while the rinsing liquid is provided to the first surface of the substrate. For example, the system may be configured to spin the substrate at from about 1000 rpm to about 3000 rpm, or from about 1200 rpm to about 2800 rpm, or from about 1400 rpm to about 2600 rpm, or from about 1600 rpm to about 2400 rpm. The system may be configured to adjust the rotational velocity based on the measurement of the measurement system. The rotational velocity of the substrate may be either increased or decreased based on the measured property.

The system of the invention may be configured to adjust the liquid pressure of the rinsing liquid based on the measurement of the measurement system. The liquid pressure of the rinsing liquid may be either increased or decreased based on the measured property.

The substrate can be made of any semiconducting material known in the art that may be used to produce substrates. For example, the substrate may be a silicon wafer, a silicon nitride wafer, a silicon oxide wafer, a silicon carbide wafer, a gallium nitride wafer, a gallium arsenide wafer or an aluminium titanium carbide wafer. Preferably, the substrate is a silicon wafer, a silicon nitride wafer, or a silicon oxide wafer. The substrate may comprise one or more substrate coatings, provided that the rinsing liquid does not react with or dissolve the one or more coatings. The one or more coatings may comprise a carbon-based polymer coating.

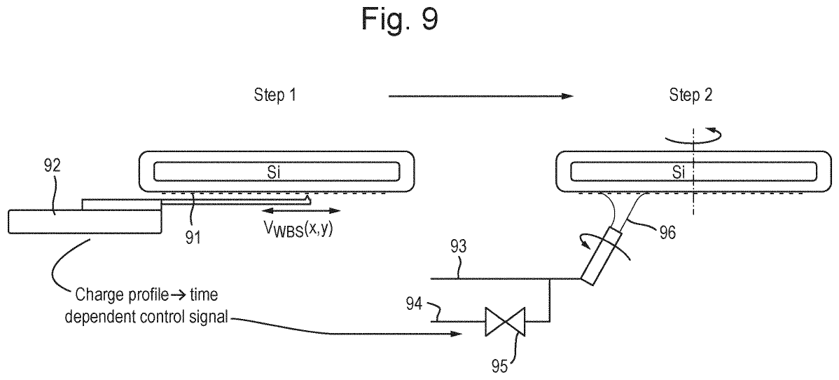

In the embodiment shown in FIG. 9, in step 1 an electrostatic voltmeter 92 is used to determine charge 91 inside or on the surface of a Si wafer. In step 2, a control valve 95 is used to add a liquid additive 94 to a water supply 93 based on the measurement of the electrostatic voltmeter 92. The resulting rinsing liquid 96 is then used to rinse the backside of the wafer. For example, the obtained charge map may be used to control the properties of the rinsing liquid. Thus, the properties of the rinsing liquid may vary as a function of position (or location) at the wafer surface.

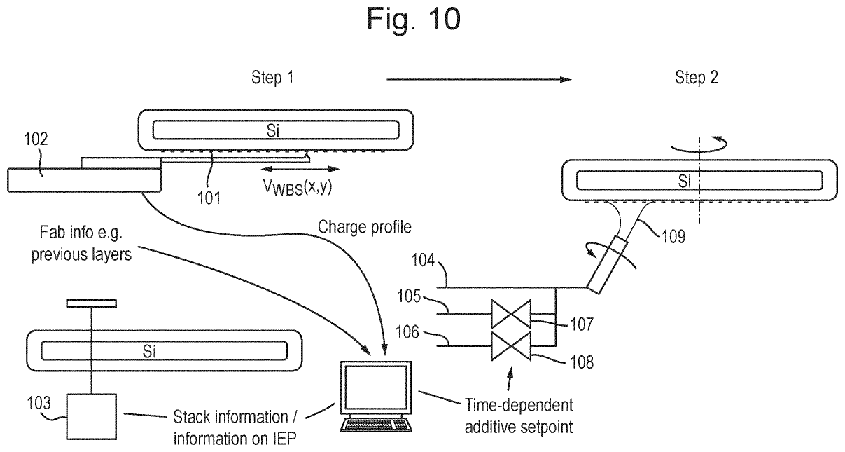

In the embodiment shown in FIG. 10, in step 1 an electrostatic voltmeter 102 is used to determine charge 101 inside or on the surface of a Si wafer. FTIR 103 is used to provide information on the structure of the wafer. This information is used, together with information regarding earlier manufacturing steps, to determine how much liquid additive 105, 106 needs to be added to a water supply 104 to produce the rinsing liquid 109. In step 2, two control valves 107, 108 are used to add two liquid additives 105, 106 to a water supply 104 based on the measurements made in step 1. The rinsing liquid 109 is then used to rinse the backside of the wafer. It will be appreciated by the skilled person that the number of additives is not limited to two additives. A plurality of additives may be used for the same purpose.

The one or more valves may be controlled by the controller arranged in the system.

The system may be part of a larger apparatus. For example, the system may be part of an apparatus used to manufacture integrated circuits. The system may be part of an apparatus configured to move the substrate into a lithographic apparatus. The system may be utilised to clean the substrate immediately prior to moving the substrate into a lithographic apparatus. Thus, the system may be part of a wafer track. In addition, the system may be a stand-alone system.

The present invention also provides a method for manufacturing a device, e.g., an integrated circuit. The method for manufacturing a device comprises processing a substrate as discussed herein.

Aspects of the invention are set out in the clauses below.

1. A method for processing a substrate, comprising: a) providing a substrate on a support; b) measuring a property of the substrate and/or of a rinsing liquid; c) controlling the addition of one or more additives to the rinsing liquid based on the measurement, to adjust the pH value and/or the conductivity of the rinsing liquid to a predetermined value; and d) providing the rinsing liquid to a first surface of the substrate via one or more nozzles.

2. The method according to clause 1, wherein the measured property is at least one of: (i) charge on the substrate; (ii) isoelectric point (IEP) of the first surface of the substrate when in contact with water; (iii) pH value of the rinsing liquid; and (iv) conductivity of the rinsing liquid.

3. The method according to clause 1 or clause 2, wherein the measured property is at least two of: (i) charge on the substrate; (ii) isoelectric point (IEP) of the first surface of the substrate when in contact with water; (iii) pH value of the rinsing liquid; and (iv) conductivity of the rinsing liquid.

4. The method according to any one of clauses 1 to 3, wherein, in step d), the rinsing liquid is provided to a backside surface of the substrate.

5. The method according to any one of clauses 1 to 4, wherein, in step b), a charge at a backside surface of the substrate is measured.

6. The method according to any one of clauses 1 to 5, wherein, in step b), a charge-measurement based spatial profile of the substrate is measured.

7. The method according to any one of clauses 1 to 6, wherein the measuring in step b) is performed using an electrostatic voltmeter and/or a FTIR (Fourier transmission infrared) spectrometer.

8. The method according to any one of clauses 1 to 7, wherein, in step d), providing the rinsing liquid to the surface of the substrate decreases the charge on the substrate.

9. The method according to any one of clauses 1 to 7, wherein, in step d), providing the rinsing liquid to the surface of the substrate has substantially no effect on the charge on the substrate.

10. The method according to any one of clauses 1 to 9, wherein the rinsing liquid is an aqueous solution.

11. The method according to nay one of clauses 1 to 10, wherein the one or more additives are aqueous solutions.

12. The method according to any one of clauses 1 to 11, wherein the one or more additives comprise one or more organic acids.

13. The method according to clause 12, wherein the one or more organic acids comprise from 1 to 10 carbon atoms.

14. The method according to clause 12 or clause 13, wherein the one or more organic acids comprise at least one compound comprising at least one group selected from a carboxyl group, a sulfo group, a thiol group, an alcohol group, an enol group, and a phenol group.

15. The method according to any one of clauses 12 to 14, wherein the one or more organic acids comprise at least one of formic acid, acetic acid, Glycolic acid, Glyoxylic acid, Oxalic acid, Propionic acid, Acrylic acid, Propiolic acid, Lactic acid, 3-Hydroxypropionic acid, Glyceric acid, Pyruvic acid, 3-oxopropanoic acid, 2,3-dioxopropanoic acid, Malonic acid, Tartronic acid, 2,2-dihydroxypropanedioic acid, Mesoxalic acid, Glycidic acid, butyric acid, isobutyric acid, crotonic acid, isocrotonic acid, methacrylic acid, vinylacetic acid, tetrolic acid, acetoacetic acid, succinic acid, fumaric acid, maleic acid, malic acid, tartaric acid, oxaloacetic acid, valeric acid, caproic acid, citric acid, aconitic acid, isocitric acid, sorbic acid, enanthic acid, pimelic acid, benzoic acid, salicylic acid, caprylic acid, phthalic acid, sophthalic acid, terephthalic acid, pelargonic acid, trimesic acid, cinnamic acid, capric acid, sebacic acid, glutaric acid, adipic acid, pimelic acid, trifluoroacetic acid and uric acid.

16. The method according to any one of clauses 12 to 15, wherein the one or more organic acids comprise at least one compound comprising a carboxyl group.

17. The method according to any one of clauses 12 to 16, wherein the one or more organic acids comprise from 1 to 3 carbon atoms.

18. The method according to any one of clauses 12 to 17, wherein the one or more organic acids comprise at least one of formic acid, acetic acid, or propionic acid.

19. The method according to any one of clauses 12 to 18, wherein the one or more organic acids comprise acetic acid.

20. The method according to any one of clauses 12 to 19, wherein the one or more organic acids have boiling points of from about 80 to about 150° C. at a pressure of 1 atm.

21. The method according to any one of clauses 1 to 20, wherein, in step c), the one or more additives is introduced to the rinsing liquid by actuating one or more control valves.

22. The method according to any one of clauses 1 to 21, wherein the method further comprises measuring the pH of the rinsing liquid following addition of the one or more additives in step c).

23. The method according to any one of clauses 1 to 22, wherein, in step c), the pH value of the rinsing liquid is adjusted to a predetermined value; and the predetermined pH value is from about 1 to about 4.5, optionally from about 1 to about 3, optionally from about 1 to about 2.

24. The method according to any one of clauses 1 to 23, wherein, in step c), the conductivity of the rinsing liquid is adjusted to a predetermined value; and the predetermined conductivity value is greater than about 0.1 mS/cm.

25. The method according to any one of clauses 1 to 24, wherein, in step c), the conductivity of the rinsing liquid is adjusted to a predetermined value; and the predetermined conductivity value is greater than about 0.5 mS/cm.

26. The method according to any one of clauses 1 to 25, wherein the substrate is a silicon wafer, a silicon nitride wafer, a silicon oxide wafer, a silicon carbide wafer, a gallium nitride wafer, a gallium arsenide wafer or an aluminium titanium carbide wafer; preferably wherein the substrate is a silicon wafer, a silicon nitride wafer, or a silicon oxide wafer.

27. A system for processing a substrate, comprising: a) a support for supporting the substrate; b) one or more nozzles arranged to provide a rinsing liquid to a first surface of the substrate; c) a measurement system configured to measure a property of the substrate and/or the rinsing liquid; and d) a controller configured to adjust the pH value and/or the conductivity of the rinsing liquid based on the measurement of the measurement system, by controlling the addition of one or more additives to the rinsing liquid.

28. The system according to clause 27, wherein the measurement system is configured to measure at least one of: (i) charge on the substrate; (ii) isoelectric point (IEP) of the first surface of the substrate when in contact with water; (iii) pH value of the rinsing liquid; and (iv) conductivity of the rinsing liquid.

29. The system according to clause 27 or clause 28, wherein the measurement system is configured to measure at least two of: (i) charge on the substrate; (ii) isoelectric point (IEP) of the first surface of the substrate when in contact with water; (iii) pH value of the rinsing liquid; and (iv) conductivity of the rinsing liquid.

30. The system according to any one of clauses 27 to 29, wherein each of the one or more nozzles is arranged to provide the rinsing liquid to a backside surface of the substrate.

31. The system according to any one of clauses 27 to 30, wherein the measurement system is configured to measure a charge at a backside surface of the substrate.

32. The system according to any one of clauses 27 to 31, wherein the measurement system is configured to provide a charge-measurement based spatial profile of the substrate.

33. The system according to any one of clauses 27 to 32, wherein the measurement system comprises an electrostatic voltmeter and/or a FTIR (Fourier transmission infrared) spectrometer.

34. The system according to any one of clauses 27 to 33, wherein the rinsing liquid is an aqueous solution.

35. The system according to any one of clauses 27 to 34, wherein the one or more additives are aqueous solutions.

36. The system according to any one of clauses 27 to 35, wherein the one or more additives comprise one or more organic acids.

37. The system according to any one of clauses 27 to 36, wherein the system comprises one or more actuators and one or more control valves; wherein each of the one or more control valves is configured to control the addition of one or more aqueous additives to the rinsing liquid.

38. The system according to any one of clauses 27 to 37, wherein the substrate is a silicon wafer, a silicon nitride wafer, a silicon oxide wafer, a silicon carbide wafer, a gallium nitride wafer, a gallium arsenide wafer or an aluminium titanium carbide wafer; preferably wherein the substrate is a silicon wafer, a silicon nitride wafer, or a silicon oxide wafer.

39. The system according to any one of clauses 27 to 38, wherein the system is part of an apparatus configured to move the substrate into a lithographic apparatus.

40. A method of manufacturing a device comprising the method for processing a substrate according to any one of clauses 1 to 26.

While the present invention has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A method for comprising:
measuring a property of a substrate and/or of a rinsing liquid, the measuring the property of the substrate comprising obtaining a charge-measurement based spatial profile of the substrate;
controlling the addition of one or more additives to the rinsing liquid based on the measurement, to adjust the pH value and/or the conductivity of the rinsing liquid to a predetermined value; and
providing the rinsing liquid to a first surface of the substrate via one or more nozzles.

2. The method according to claim 1, wherein the measured property comprises at least one selected from: (i) charge on the substrate; (ii) isoelectric point (IEP) of the surface of the substrate when in contact with water; (iii) pH value of the rinsing liquid; and/or (iv) conductivity of the rinsing liquid.

3. The method according to claim 1, wherein the measured property comprises at least two selected from: (i) charge on the substrate; (ii) isoelectric point (IEP) of the surface of the substrate when in contact with water; (iii) pH value of the rinsing liquid; and/or (iv) conductivity of the rinsing liquid.

4. The method according to of claim 1, wherein, the rinsing liquid is provided to a backside of the substrate.

5. The method according to claim 1, wherein, in the measuring, a charge at a backside of the substrate is measured.

6. (canceled)

7. The method according to claim 1, wherein the measuring the property of the substrate is performed using an electrostatic voltmeter and/or a FTIR (Fourier transmission infrared) spectrometer.

8. The method according to claim 1, wherein, providing the rinsing liquid to the surface of the substrate decreases the charge on the substrate.

9. The method according to claim 1, wherein the one or more additives comprise one or more organic acids.

10. The method according to claim 9, wherein the one or more organic acids comprise at least one compound comprising at least one group selected from: a carboxyl group, a sulfo group, a thiol group, an alcohol group, an enol group, and/or a phenol group.

11. A system for processing a substrate, the system comprising:
a support to support the substrate;
one or more nozzles arranged to provide a rinsing liquid to a surface of the substrate;
a measurement system configured to measure a property of the substrate and of the rinsing liquid, wherein the measurement system is configured to provide a charge-measurement based spatial profile of the substrate; and
a controller configured to adjust the pH value and/or the conductivity of the rinsing liquid based on the measurement of the measurement system, by controlling the addition of one or more additives to the rinsing liquid.

12. The system according to claim 11, wherein the measurement system is configured to measure at least one selected from: (i) charge on the substrate; (ii) isoelectric point (IEP) of the first surface of the substrate when in contact with water; (iii) pH value of the rinsing liquid; and/or (iv) conductivity of the rinsing liquid.

13. The system according to claim 11, wherein the measurement system is configured to measure at least two selected from: (i) charge on the substrate; (ii) isoelectric point (IEP) of the surface of the substrate when in contact with water; (iii) pH value of the rinsing liquid; and/or (iv) conductivity of the rinsing liquid.

14. The system according to claim 11, wherein each of the one or more nozzles is arranged to provide the rinsing liquid to a backside of the substrate.

15. The system according to claim 11, wherein the measurement system is configured to measure a charge at a backside of the substrate.

16. The system according to claim 11, wherein the measurement system comprises an electrostatic voltmeter and/or a FTIR (Fourier transmission infrared) spectrometer.

17. The system according to claim 11, wherein the one or more additives comprise one or more organic acids.

18. The system according to claim 17, wherein the one or more organic acids comprise at least one compound comprising at least one group selected from: a carboxyl group, a sulfo group, a thiol group, an alcohol group, an enol group, and/or a phenol group.

19. The system according to claim 11, wherein the system is part of an apparatus configured to move the substrate into a lithographic apparatus.

20. The method according to claim 1, wherein, in controlling the addition of one or more additives, the pH value of the rinsing liquid is adjusted to a predetermined value from about 1 to about 4.5.

21. The method according to claim 1, wherein, in controlling the addition of one or more additives, the conductivity of the rinsing liquid is adjusted to a predetermined conductivity value greater than about 0.1 mS/cm.
